(19) United States
(12) Patent Application Publication
(10) Pub. No.: US 2017/0352495 A1
(43) Pub. Date: Dec. 7, 2017

(54) CAPACITOR MODULE

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-shi, Osaka (JP)

(72) Inventor: Shinichiro Sato, Yokkaichi, Mie (JP)

(21) Appl. No.: 15/541,779

(22) PCT Filed: Dec. 21, 2015
(86) PCT No.: PCT/JP2015/085650

§ 371 Date: Jul. 6, 2017

(30) Foreign Application Priority Data
Jan. 8, 2015 (JP) 2015-002101

(51) Int. Cl. H01G 11/10; H01G 11/76; H05K 1/18; H05K 5/00

(52) U.S. Cl. CPC H01G 11/10; H05K 5/0026; H01G 11/76; H05K 1/18; H05K 2201/10015

(57) ABSTRACT

A capacitor module has a module case including a lower case and an upper case. A housing case is fixed to an inner face of the upper case, and a capacitor is housed in the housing case. A circuit board is fixed to an upper face of the lower case. The circuit board has wiring that is electrically connectable to the capacitor, and electronic components and constituting a circuit that controls electric current to the capacitor are mounted on the circuit board.

### CROSS-REFERENCE TO RELATED APPLICATIONS

This application is the U.S. national stage of PCT/JP2015/085650 filed Dec. 21, 2015, which claims priority of Japanese Patent Application No. JP 2015-002101 filed Jan. 8, 2015.

### TECHNICAL FIELD

The present invention relates to a capacitor module.

### BACKGROUND

Conventionally, various load apparatuses installed in a vehicle operate based on electric power that can be supplied from a battery. Operation of each load apparatus is not guaranteed when there is a power failure due to a battery failure, a reduction in voltage, or the like. Therefore, a backup power supply apparatus having a power storage member such as a large-capacity capacitor has been proposed. The large-capacity capacitor can be housed in a case fixed to a circuit board, and mounted on the circuit board (see, for example, JP 2009-253009A).

Incidentally, various electronic components can be mounted on a circuit board. However, as described above, when a case housing a large-capacity capacitor is fixed on the circuit board, the arrangement of electronic components is restricted by the case. Such arrangement restriction leads to an increase in the size of the circuit board, which in turn leads to an increase in the size of a module that houses the circuit board.

An object of the present invention is to reduce the size of a capacitor module.

A capacitor module according to one aspect of the present invention includes: a module case including a lower case and an upper case; a housing case fixed to an inner face of the upper case; a capacitor housed in the housing case; a circuit board fixed to an upper face of the lower case, the circuit board having wiring electrically connectable to the capacitor, and electronic components constituting a circuit that controls electric current to the capacitor being mounted to the circuit board; and an external connection connector fixed to the lower case and including a terminal connected to wiring of the circuit board.

According to this configuration, the housing case that houses the capacitor is fixable to the upper case of the module case. Also, the circuit board to which the capacitor is connectable is fixable to the lower case of the module case. Therefore, because the circuit board and the housing case are separated from each other, electronic components can be mounted in a region where the circuit board and the housing case overlap in a plan view, and therefore, the size of the circuit board and the module case can be reduced.

In the above capacitor module, it is preferable that the upper case has an upper plate that fixedly supports the housing case, a side plate extending from an end portion of the upper plate in a direction orthogonal to the upper plate, and a terminal holding plate fixed to the side plate and holding a terminal of the capacitor.

According to this configuration, the capacitor can be housed in the housing case fixed to the upper plate of the upper case. A terminal of the capacitor can be fixed to a side plate extending from the upper plate in a direction orthogonal to the upper plate. Therefore, the terminal of the capacitor is less likely to move relative to the upper case.

In the above capacitor module, it is preferable that the capacitor has a capacitor body that can be housed in the housing case, and a lead wire that protrudes from the capacitor body, and the circuit board has a connection hole where the lead wire of the capacitor can be electrically connected.

According to this configuration, the capacitor held in the upper case has a capacitor body that can be housed in the housing case and a lead wire that protrudes from the capacitor body. The lead wire can be electrically connected to the connection hole formed in the circuit board.

In the above capacitor module, it is preferable that the lead wire of the capacitor has a press-fit terminal having a press-in portion that is wider than an inner diameter of the connection hole at its tip and is elastically deformable, and the press-in portion of the press-fit terminal is pressed into the connection hole of the circuit board.

According to this configuration, the lead wire has a press-fit terminal at its tip, and the press-fit terminal is pressed into the connection hole of the circuit board, so the capacitor is easily connected to the circuit board.

In the above capacitor module, it is preferable that the press-fit terminal has an attachment portion that protrudes in a direction orthogonal to the lead wire, and the terminal holding plate is arranged closer to the capacitor body side than the attachment portion, and holds the press-fit terminal.

According to this configuration, the press-fit terminal has an attachment portion, and the terminal holding plate fixed to the upper case can be arranged closer to the capacitor body side than the attachment portion. By the terminal holding plate engaging with the attachment portion, the press-fit terminal can be pressed into the connection hole.

In the above capacitor module, it is preferable that the electronic component includes an electronic component mounted on a lower case side mounting face of the circuit board, and an electronic component mounted on a capacitor side mounting face opposite to the lower case side mounting face of the circuit board, the heating quantity of the electronic component mounted on the lower case side mounting face being larger than the heating quantity of the electronic component mounted on the capacitor side mounting face.

According to this configuration, electronic components can be mounted on both sides of the circuit board, and electronic components with a larger heating quantity can be mounted on the face of the lower case side. Therefore, heat of the electronic components is less likely to be transferred to the capacitor, and a temperature increase of the capacitor is suppressed.

In the above capacitor module, it is preferable that the housing case and the circuit board face each other with an open space therebetween, and at least one of the electronic components faces the housing case in the open space.

According to this configuration, it is possible to reduce the footprint of the circuit board, and it is possible to reduce the size of the module case.

According to the present invention, it is possible to reduce the size of the capacitor module.

### BRIEF DESCRIPTION OF DRAWINGS

FIG. 1 is a partial side cross-sectional view of a capacitor module of an embodiment.

FIG. 2 is a partial cross-sectional view for describing assembly of a lower case and an upper case of the capacitor module.

FIG. 3 is a plan view of the capacitor module.

FIG. 4 is a perspective view of capacitors and a housing case.

FIG. 5 is an exploded perspective view of a module case.

FIG. 6 illustrates a press-fit terminal.

### DETAILED DESCRIPTION OF PREFERRED EMBODIMENTS

Following is a description of a capacitor module of an embodiment. Note that in the accompanying drawings, there are cases where constituent elements are shown enlarged for easy understanding. Also, there are cases where the dimensional proportions of the constituent elements differ from actual elements or from those in other drawings.

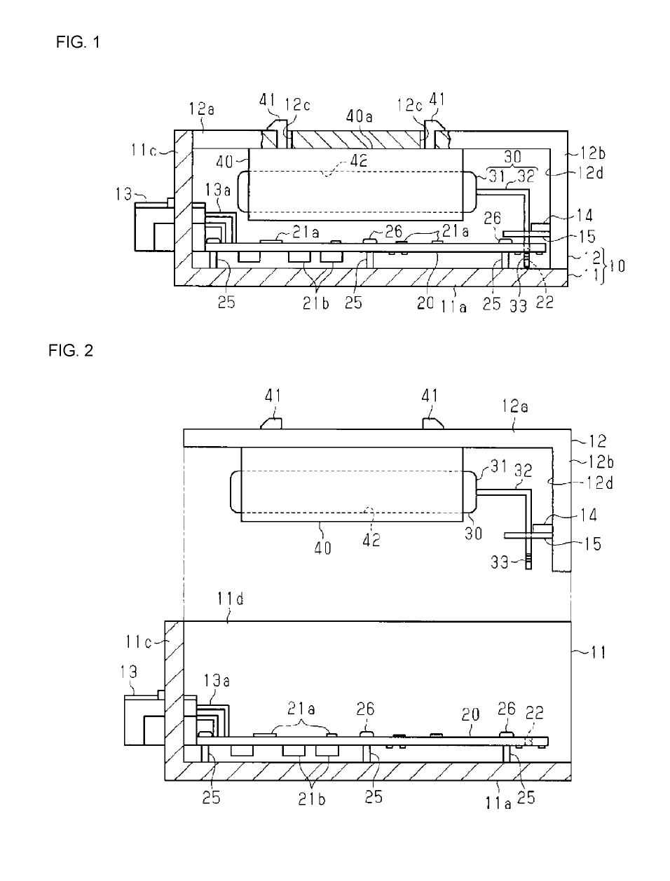

As shown in FIG. 1, the capacitor module includes a module case 10, a circuit board 20 housed in the module case 10, and a plurality of capacitors 30. The capacitors 30 are, for example, electric double layer capacitors.

The module case 10 is formed in a substantially rectangular parallelepiped shape. The module case 10 is made of synthetic resin, for example. The module case 10 can include an unshown attachment portion for attaching the module case 10 to a vehicle.

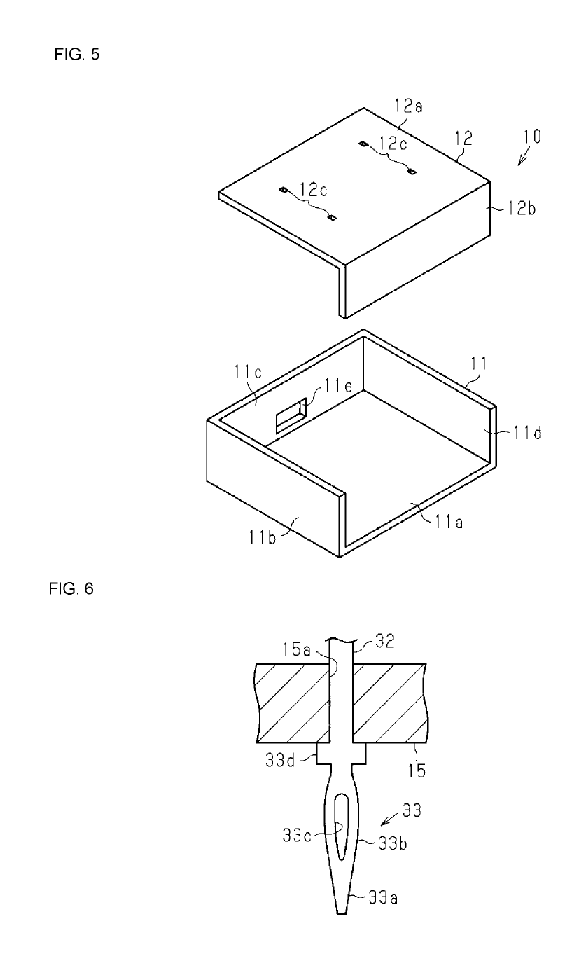

The module case 10 includes a lower case 11, and an upper case 12 attachable to the lower case 11. As shown in FIG. 5, the lower case 11 has a rectangular plate-like base plate 11a and side plates 11b, 11c, and 11d standing at end portions of the base plate 11a. A through hole 11e is formed in the side plate 11c, and an external connection connector 13 shown in FIG. 1 is attachable at the through hole 11e.

The upper case 12 has an upper plate 12a and a side plate 12b, and can be a substantially L-shaped cover. The upper case 12 is attached to the lower case 11, for example, by snap-fitting, and defines an internal space of the module case 10.

As shown in FIG. 2, the circuit board 20 is attached to the base plate 11a of the lower case 11. The circuit board 20 is supported apart from the base plate 11a by support columns 25 between the circuit board 20 and the base plate 11a of the lower case 11, and fixed to the lower case 11 by screws 26 used as fixing members. The length of the support columns 25, that is, the distance between the base plate 11a of the lower case 11 and the circuit board 20, is set according to electronic components to be mounted on the circuit board 20.

A lead 13a of the external connection connector 13 is connected by, for example, soldering to the circuit board 20.

A plurality of electronic components 21a and 21b are mounted on the circuit board 20. The electronic components 21a and 21b constitute a control circuit that controls charging current and discharging current for the capacitors 30.

The electronic components 21a mounted on the upper face (also referred to as a capacitor side mounting face) of the circuit board 20 are microcomputers logic ICs, small-signal system transistors, or the like. These electronic components 21a have low power consumption and generate little heat.

The electronic components 21b mounted on the lower face (also referred to as a lower case side mounting face) of the circuit board 20 are switching elements such as MOS transistors, elements constituting a snubber circuit, rectifier diodes, bypass capacitors, or the like. These electronic components 21b generate much heat.

In the upper case 12, a housing case 40 is fixed to the lower face of the upper plate 12a, and a plurality of the capacitors 30 are housed in the housing case 40.

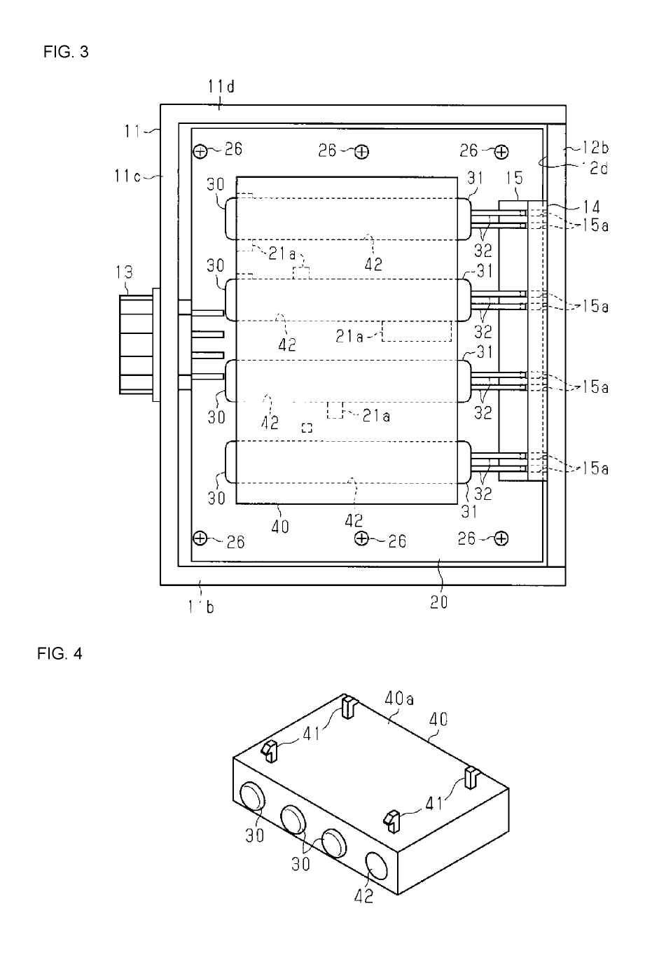

As shown in FIG. 3, four of the capacitors 30 are housed in the housing case 40.

A capacitor 30 has a capacitor body 31 and a pair of lead wires 32. The capacitor body 31 is formed in, for example, a cylindrical shape, and houses an electric storage element.

As shown in FIG. 4, the housing case 40 is formed in a substantially rectangular parallelepiped shape. On an upper face 40a of the housing case 40, a plurality of (four in FIG. 4) engaging portions 41 are formed protruding from the upper face 40a. As shown in FIG. 5, a plurality (four in FIG. 5) of corresponding insertion holes 12c are formed in the upper plate 12a of the upper case 12. As shown in FIG. 1, the engaging portions 41 of the housing case 40 are inserted into the insertion holes 12c of the upper case 12 (the upper plate 12a). The engaging portions 41 are, for example, snap-fit portions, and engage with the upper plate 12a to fix the housing case 40 to the upper case 12 (the upper plate 12a). In this way, the housing case 40 housing the capacitors 30 can be integrated with the upper case 12 (the upper plate 12a).

As shown in FIG. 3, a plurality (four) of housing holes 42 corresponding to the number of capacitors 30 to be housed are formed in the housing case 40.

As shown in FIG. 4, the housing holes 42 are formed in a cylindrical shape corresponding to the shape of the capacitor bodies 31, and hold the inserted capacitor bodies 31. In this drawing, a capacitor corresponding to one housing hole 42 is omitted. For example, the housing case 40 has ribs (not shown) arranged in the circumferential direction on the inner face of the housing holes 42. The ribs are formed so as to extend in the insertion direction of the capacitors 30. The diameter of a circle connecting apexes of the plurality of ribs is set to be slightly smaller than the diameter of a capacitor body 31. Therefore, a capacitor body 31 that has been inserted into a housing hole 42 is held by the housing case 40.

As shown in FIG. 2, the lead wires 32 of a capacitor 30 are led out from a circular end face of the capacitor body 31 in a direction orthogonal to this end face. Further, the pair of lead wires 32 are formed bent in an L shape in a side view so as to extend toward the circuit board 20. The lead wires 32 are supported by an attachment portion 14 formed on an inner face 12d of the side plate 12b of the upper case 12, and a terminal holding plate 15 fixed to the attachment portion 14.

As shown in FIG. 3, slits 15a into which the lead wires 32 are inserted are formed in the terminal holding plate 15. The terminal holding plate 15 with the lead wires 32 inserted into the slits 15a is fixed to the attachment portion 14, for example, by snap-fitting. Note that the terminal holding plate 15 may also be fixed to the attachment portion 14 using, for example, an adhesive, welding, screws, or the like.

As shown in FIG. 2, connection holes 22 where the pairs of lead wires 32 of the plurality of capacitors 30 are respectively connected are formed in the circuit board 20. The connection hole 22 is a through hole having conductivity and has an electric conductor such as metal plating formed on its inner face, and electrically connects a pattern on the circuit board 20 to the lead wires 32.

As shown in FIG. 6, a lead wire 32 has a press-fit terminal 33 at its tip. The press-fit terminal 33 has, in order from the tip, a guide portion 33a, a press-in portion 33b, and an attachment portion 33d. The guide portion 33a is formed in a narrow-tipped (tapered) shape with a narrow tip. The guide portion 33a facilitates the insertion of the lead wire 32 into the connection hole 22 of the circuit board 20 shown in FIG. 2.

The press-in portion 33b protrudes in a direction orthogonal to the length direction (the vertical direction in FIG. 6). The width of the press-in portion 33b is greater than the inner diameter of the connection hole 22 of the circuit board 20 shown in FIG. 2. At the center of the press-in portion 33b, a window portion 33c extending in the length direction is formed. The window portion 33c enables deformation such that the press-in portion 33b is elastically reduced in diameter.

The attachment portion 33d protrudes outward on both sides in a direction orthogonal to the extending direction of the press-fit terminal 33 (the axial direction of the press-fit terminal 33, and the vertical direction in FIG. 6). The attachment portion 33d is formed in, for example, a rectangular shape. The attachment portion 33d engages with the terminal holding plate 15, and presses the press-in portion 33b of the press-fit terminal 33 at the time of connection into the connection hole 22 (see FIG. 2).

Next, operation of the above capacitor module will be described.

As shown in FIG. 1, the housing case 40 that houses the capacitor 30 is fixable to the upper case 12 of the module case 10. The circuit board 20 to which the capacitor 30 is connectable is fixable to the lower case 11 of the module case 10. Therefore, because the circuit board 20 and the housing case 40 are separated from each other, the electronic components 21a can be mounted in a region where the circuit board 20 and the housing case 40 overlap in a plan view. Therefore, the surface area of the circuit board 20 where the electronic components 21a are mountable can be reduced. Also, it is possible to achieve a reduction in the surface area of the module case 10 that houses the circuit board 20, that is, the surface area required for fixing the capacitor module.

The capacitor 30 can be housed in the housing case 40 fixed to the upper plate 12a of the upper case 12. The terminals of the capacitor 30 are fixable to the side plate 12b extending from the upper plate 12a in the direction orthogonal to the upper plate 12a. Therefore, relative movement of the lead wires 32 of the capacitor 30 with respect to the upper case 12 is prevented or reduced. Relative movement of the lead wires 32 of the capacitor 30 causes disconnection of the lead wires 32 or poor connection with the circuit board. Therefore, by suppressing the relative movement of the lead wires 32, occurrence of defects is suppressed.

The capacitor 30 held by the upper case 12 has the capacitor body 31 that can be housed in the housing case 40 and the lead wires 32 that protrude from the capacitor body 31. The lead wires 32 are electrically connectable to the connection holes 22 formed in the circuit board 20. The charging current and discharging current for the capacitor 30 are controlled by a control circuit constituted by the electronic components 21a and 21b mounted on the circuit board 20.

Each lead wire 32 has a press-fit terminal 33 at its tip, and the press-fit terminal 33 is pressed into the connection hole 22 of the circuit board 20, and thus the capacitor 30 is easily connected to the circuit board 20.

The press-fit terminal 33 has the attachment portion 33d, and the terminal holding plate 15 fixed to the upper case 12 can be arranged closer to the capacitor body 31 side than the attachment portion 33d. The terminal holding plate 15 engages with the attachment portion 33d to restrict movement of the press-fit terminal 33, and thus the press-fit terminal 33 is pressed into the connection hole 22.

The electronic components 21a and 21b can be mounted on both faces of the circuit board 20, and the electronic components 21b, which have a larger heating quantity, can be mounted on the face of the side of the lower case 11. Therefore, the heat of the electronic components 21b is less likely to be transferred to the capacitor 30, and a temperature increase of the capacitor 30 is suppressed.

As described above, according to the present embodiment, the following effects are exhibited.

(1) The capacitor module has the module case 10 composed of the lower case 11 and the upper case 12. The housing case 40 is fixable to the inner face of the upper case 12, and the capacitor 30 can be housed in the housing case 40. The circuit board 20 is fixed to the upper face of the lower case 11. The circuit board 20 has wiring electrically connectable to the capacitor 30, and the electronic components 21a and 21b constituting a circuit that controls current to the capacitor 30 are mounted on the circuit board 20. Also, the circuit board 20 is connectable to an apparatus (for example, a brake control apparatus or the like) outside the module through the external connection connector 13 fixed to the lower case 11.

The housing case 40 that houses the capacitor 30 is fixable to the upper case 12 of the module case 10. The circuit board 20 to which the capacitor 30 is connectable is fixable to the lower case 11 of the module case 10. Therefore, because the circuit board 20 and the housing case 40 are separated from each other, the electronic components 21a can be mounted in a region where the circuit board 20 and the housing case 40 overlap in a plan view, and thus the size of the circuit board 20 and the module case 10 can be reduced. Also, it is possible to achieve a reduction in the surface area of the module case 10 that houses the circuit board 20, that is, the surface area required for fixing the capacitor module.

(2) The capacitor 30 can be housed in the housing case 40 fixed to the upper plate of the upper case 12. The terminal of the capacitor 30 is fixable to a side plate extending from the upper plate in a direction orthogonal to the upper plate. Therefore, the terminal of the capacitor 30 is less likely to move relative to the upper case 12. In the capacitor 30, relative movement of the lead wires 32 causes disconnection of the lead wires 32 or poor connection with the circuit board. Therefore, by suppressing the relative movement of the lead wires 32, occurrence of defects can be suppressed.

(3) The capacitor 30 held by the upper case 12 has the capacitor body 31 that can be housed in the housing case 40, and lead wires protruding from the capacitor body 31. The lead wires are electrically connectable to the connection holes formed in the circuit board 20. The charging current and discharging current for the capacitor 30 can be controlled by a control circuit constituted by the electronic components 21a and 21b mounted on the circuit board 20.

(4) Each lead wire 32 has a press-fit terminal at its tip, and the press-fit terminal is pressed into the connection hole of the circuit board 20. Therefore, the capacitor 30 can be easily connected to the circuit board 20. Connection of the capacitor 30 to the circuit board 20 is performed at the time of assembling the lower case 11 and the upper case 12. That is, because the capacitor 30 is connected to the circuit board 20 at the same time as assembling the upper case 12 to the lower case 11, a step of connecting the capacitor 30 to the circuit board 20 is unnecessary, and so it is possible to reduce the number of manufacturing steps, the amount of time for manufacturing, and the like.

(5) The press-fit terminal 33 has the attachment portion 33d, and the terminal holding plate 15 fixed to the upper case 12 can be arranged closer to the capacitor body 31 side than the attachment portion 33d. The terminal holding plate 15 engages with the attachment portion 33d to restrict movement of the press-fit terminal 33, and thus the press-fit terminal 33 can be reliably pressed into the connection hole 22.

(6) The electronic components 21a and 21b can be mounted on both faces of the circuit board 20, and the electronic components 21b with a large heating quantity can be mounted on the face on the side of the lower case 11. Therefore, heat of the electronic components 21b is less likely to be transferred to the capacitor 30, so a temperature increase of the capacitor 30 can be suppressed. A temperature increase of the capacitor 30 lowers properties and its useful life. Therefore, by mounting the electronic components 21b in this manner, it is possible to suppress a reduction in the performance of the capacitor 30, and achieve a longer life.

(7) The housing case 40 and the circuit board 20 are arranged between the top plate and the bottom plate (that is, between the upper plate 12a of the upper case 12 and the base plate 11a of the lower case 11) of the module case 10. The housing case 40 and the circuit board 20 face each other with an open space (empty space) therebetween. At least one electronic component 21a mounted on the circuit board 20 faces the housing case 40 in the open space (see FIG. 1). According to this configuration, the footprint of the circuit board 20 can be reduced, and the size of the module case 10 can be reduced.

Note that the embodiment may also be modified as follows.

In the above embodiment, the number of capacitors 30 is four, but the number of capacitors may be appropriately changed to three or less, or five or more.

In the above embodiment, the housing case 40 is integrally fixed to the upper case 12 by the engaging portions 41 of the upper face 40a of the housing case 40, but the method of fixing the housing case 40 is not limited to this method. For example, an engaging portion of the side plate 12b of the upper case 12 and an engaging portion of a side face of the housing case 40 may be fixed by snap-fitting. Also, the housing case 40 may be fixed to the upper case 12 by screws (bolts and nuts) or the like.

The housing case 40 is not limited to being divided into the cases 11 and 12 of the shape shown in the drawings, and may also be divided in various ways. For example, the housing case 40 may also be equally or unequally divided in the vertical direction in FIG. 1.

The present invention is not limited to the exemplary configuration disclosed above. For example, the exemplary disclosed features should not be interpreted as being essential to the present invention, and the subject matter of the present invention may also exist in fewer features than all of the features of the specific embodiment that was disclosed.

1. A capacitor module, comprising:
a module case including a lower case and an upper case;
a housing case fixed to an inner face of the upper case;
at least one capacitor housed in the housing case;
a circuit board fixed to an upper face of the lower case, the circuit board having wiring electrically connectable to the at least one capacitor, and electronic components constituting a circuit that controls electric current to the at least one capacitor being mounted to the circuit board; and
an external connection connector fixed to the lower case and including a terminal connected to wiring of the circuit board.

2. The capacitor module according to claim 1,
wherein the upper case includes:
an upper plate that fixedly supports the housing case,
a side plate extending from an end portion of the upper plate in a direction orthogonal to the upper plate, and
a terminal holding plate fixed to the side plate and holding a terminal of the at least one capacitor.

3. The capacitor module according to claim 2,
wherein the at least one capacitor has a capacitor body that can be housed in the housing case, and a lead wire that protrudes from the capacitor body, and
the circuit board has a connection hole where the lead wire of the at least one capacitor can be electrically connected.

4. The capacitor module according to claim 3,
wherein the lead wire of the at least one capacitor has a press-fit terminal having a press-in portion that is wider than an inner diameter of the connection hole at its tip and is elastically deformable, and
the press-in portion of the press-fit terminal is pressed into the connection hole of the circuit board.

5. The capacitor module according to claim 4,
wherein the press-fit terminal has an attachment portion that protrudes in a direction orthogonal to the lead wire, and
the terminal holding plate is arranged closer to the capacitor body side than the attachment portion, and holds the press-fit terminal.

6. The capacitor module according to claim 1,
wherein the electronic component includes an electronic component mounted on a lower case side mounting face of the circuit board, and an electronic component mounted on a capacitor side mounting face opposite to the lower case side mounting face of the circuit board,
the heating quantity of the electronic component mounted on the lower case side mounting face being larger than the heating quantity of the electronic component mounted on the capacitor side mounting face.

7. The capacitor module according to claim 1,
wherein the housing case and the circuit board face each other with an open space therebetween, and at least one of the electronic components faces the housing case in the open space.

8. The capacitor module according to claim 2, wherein the electronic component includes an electronic component mounted on a lower case side mounting face of the circuit board, and an electronic component mounted on a capacitor side mounting face opposite to the lower case side mounting face of the circuit board, the heating quantity of the electronic component mounted on the lower case side mounting face being larger than the heating quantity of the electronic component mounted on the capacitor side mounting face.

9. The capacitor module according to claim 3, wherein the electronic component includes an electronic component mounted on a lower case side mounting face of the circuit board, and an electronic component mounted on a capacitor side mounting face opposite to the lower case side mounting face of the circuit board, the heating quantity of the electronic component mounted on the lower case side mounting face being larger than the heating quantity of the electronic component mounted on the capacitor side mounting face.

10. The capacitor module according to claim 4, wherein the electronic component includes an electronic component mounted on a lower case side mounting face of the circuit board, and an electronic component mounted on a capacitor side mounting face opposite to the lower case side mounting face of the circuit board, the heating quantity of the electronic component mounted on the lower case side mounting face being larger than the heating quantity of the electronic component mounted on the capacitor side mounting face.

11. The capacitor module according to claim 5, wherein the electronic component includes an electronic component mounted on a lower case side mounting face of the circuit board, and an electronic component mounted on a capacitor side mounting face opposite to the lower case side mounting face of the circuit board, the heating quantity of the electronic component mounted on the lower case side mounting face being larger than the heating quantity of the electronic component mounted on the capacitor side mounting face.

12. The capacitor module according to claim 2, wherein the housing case and the circuit board face each other with an open space therebetween, and at least one of the electronic components faces the housing case in the open space.

13. The capacitor module according to claim 3, wherein the housing case and the circuit board face each other with an open space therebetween, and at least one of the electronic components faces the housing case in the open space.

14. The capacitor module according to claim 4, wherein the housing case and the circuit board face each other with an open space therebetween, and at least one of the electronic components faces the housing case in the open space.

15. The capacitor module according to claim 5, wherein the housing case and the circuit board face each other with an open space therebetween, and at least one of the electronic components faces the housing case in the open space.

16. The capacitor module according to claim 6, wherein the housing case and the circuit board face each other with an open space therebetween, and at least one of the electronic components faces the housing case in the open space.
